(19) United States
(12) Patent Application Publication
(10) Pub. No.: US 2023/0192957 A1
(43) Pub. Date: Jun. 22, 2023

(54) MODIFIED POLYBENZOXAZOLE, MODIFIED POLYBENZOXAZOLE SHEET, CLEANING SHEET, AND TRANSFER MEMBER PROVIDED WITH CLEANING FUNCTION

(71) Applicant: NITTO DENKO CORPORATION, Osaka (JP)

(72) Inventor: Yuichi FUKAMICHI, Ibaraki-shi (JP)

(21) Appl. No.: 17/961,879

(22) Filed: Oct. 7, 2022

(30) Foreign Application Priority Data
Oct. 22, 2021 (JP) 2021-173016

(51) Int. Cl. C08G 73/22; C08J 5/18; B08B 1/00

(52) U.S. Cl. CPC C08G 73/22; C08J 5/18; B08B 1/001; C08J 2379/04

(57) ABSTRACT

Provided are a modified polybenzoxazole and a modified polybenzoxazole sheet each having small temperature dependence of its modulus of elasticity, each of which may be suitably used for forming a cleaning sheet that may be suitably used for a transfer member to be transferred in a substrate processing apparatus. Also provided is a cleaning sheet having small temperature dependence of its modulus of elasticity, including such modified polybenzoxazole sheet as a cleaning layer. Also provided is a transfer member provided with a cleaning function, including such cleaning sheet and a transfer member. The modified polybenzoxazole is a modified polybenzoxazole, including a benzoxazole ring structure and two or more amide groups, the modified polybenzoxazole having a storage modulus of elasticity at 1 Hz in a range of 0° C. to 100° C. of 200 MPa to 2,000 MPa.

### CROSS-REFERENCE TO RELATED APPLICATION(S)

This application claims priority under 35 U.S.C. Section 119 to Japanese Patent Application No. 2021-173016 filed on Oct. 22, 2021, which is herein incorporated by references.

### BACKGROUND OF THE INVENTION

### 1. Field of the Invention

The present disclosure relates to a modified polybenzoxazole, a modified polybenzoxazole sheet, a cleaning sheet, and a transfer member provided with a cleaning function.

### 2. Description of the Related Art

In various kinds of substrate processing apparatus that are liable to be damaged by foreign matter, such as production apparatus and inspection apparatus for a semiconductor, a flat panel display, a printed board, and the like, a transfer device (typically a chuck table or the like) and a substrate are transferred while being brought into physical contact with each other. In this case, when foreign matter adheres to the transfer device, the subsequent substrates are contaminated one after another, and hence it is necessary to stop the apparatus periodically so as to clean the apparatus. As a result, there arise problems in that the operation rate of the processing apparatus decreases, and that a great amount of time and labor are required for cleaning the apparatus.

In order to solve such problems as described above, a method of removing foreign matter adhering to a transfer device by transferring a plate-shaped member in a substrate processing apparatus (see Japanese Patent Application Laid-open No. H11-87458) has been proposed. According to this method, it is not necessary to stop a substrate processing apparatus so as to clean the apparatus, and hence the problem of a decrease in the operation rate of the processing apparatus is solved. According to this method, however, it has been impossible to sufficiently remove the foreign matter adhering to the transfer device.

Meanwhile, a method of removing foreign matter adhering to a transfer device by transferring a substrate with an adherent material adhering thereto as a cleaning member in a substrate processing apparatus (see Japanese Patent Application Laid-open No. H10-154686) has been proposed. This method provides excellent foreign matter removing performance as compared to the method described in Japanese Patent Application Laid-open No. H11-87458. In the method described in Japanese Patent Application Laid-open No. H10-154686, however, there may arise a problem in that the adherent material and the transfer device are bonded to each other so strongly in a contact portion therebetween that the material and the device are not separated from each other. As a result, there may arise a problem in that the substrate with the adherent material adhering thereto cannot be securely transferred, a problem in that the transfer device is damaged, and a problem in that the transfer device is contaminated. Meanwhile, when an adhesive strength between the adherent material and the transfer device becomes excessively small, there may arise a problem in that the foreign matter removing performance of the cleaning member reduces, and hence a sufficient cleaning effect is not obtained.

As means for solving, for example, such various problems as described above, the applicant has reported a cleaning sheet including a cleaning layer containing a modified polybenzoxazole having a specific soft segment (Japanese Patent Application Laid-open No. 2021-86875).

In this connection, the cleaning sheet preferably has a wide usable temperature region. In addition, in order to secure a wide usable temperature region of the cleaning sheet, it is preferred that the cleaning sheet have a small temperature dependence of its modulus of elasticity. For example, in the case where the cleaning sheet is reduced in elasticity due to a large temperature dependence of its modulus of elasticity, the cleaning sheet may adsorb to a stage when used for a transfer member to be transferred in the substrate processing apparatus.

### SUMMARY OF THE INVENTION

An object of the present disclosure is to provide a modified polybenzoxazole and a modified polybenzoxazole sheet each having small temperature dependence of its modulus of elasticity, each of which may be suitably used for forming a cleaning sheet that may be suitably used for a transfer member to be transferred in a substrate processing apparatus. Another object of the present disclosure is to provide a cleaning sheet having small temperature dependence of its modulus of elasticity, including such modified polybenzoxazole sheet as a cleaning layer. Still another object of the present disclosure is to provide a transfer member provided with a cleaning function, including such cleaning sheet and a transfer member.

According to at least one embodiment of the present disclosure, there is provided a modified polybenzoxazole, including a benzoxazole ring structure and two or more amide groups, the modified polybenzoxazole having a storage modulus of elasticity at 1 Hz in a range of 0° C. to 100° C. of 200 MPa to 2,000 MPa.

In at least one embodiment, a change ratio of the storage modulus of elasticity at 1 Hz in a range of 0° C. to 100° C. is 50% or less.

In at least one embodiment, the modified polybenzoxazole according to at least one embodiment of the present disclosure has a change ratio of the storage modulus of elasticity at 25° C. in a range of 0.001 Hz to 1 Hz of 50% or less.

In at least one embodiment, the two or more amide groups are amide groups derived from a polyamine.

In at least one embodiment, the polyamine is at least one kind selected from the group consisting of a diamine compound having a polyether structure, an aliphatic diamine, and an aromatic diamine.

According to at least one embodiment of the present disclosure, there is provided a modified polybenzoxazole sheet, including the modified polybenzoxazole according to at least one embodiment of the present disclosure.

According to at least one embodiment of the present disclosure, there is provided a cleaning sheet, including a cleaning layer, wherein the cleaning layer is the modified polybenzoxazole sheet according to at least one embodiment of the present disclosure.

In at least one embodiment, the cleaning sheet according to at least one embodiment of the present disclosure further includes a pressure-sensitive adhesive layer.

In at least one embodiment, the cleaning sheet according to at least one embodiment of the present disclosure further includes a support.

According to at least one embodiment of the present disclosure, there is provided a modified transfer member provided with a cleaning function, including the cleaning sheet according to at least one embodiment of the present disclosure, and a transfer member.

### BRIEF DESCRIPTION OF THE DRAWINGS

FIG. 1 is a schematic cross-sectional view for illustrating a cleaning sheet according to at least one embodiment of the present disclosure.

FIG. 2 is a schematic cross-sectional view for illustrating a cleaning sheet according to at least one embodiment of the present disclosure.

FIG. 3 is a schematic cross-sectional view for illustrating a cleaning sheet according to at least one embodiment of the present disclosure.

FIG. 4 is a schematic cross-sectional view for illustrating a transfer member provided with a cleaning function according to at least one embodiment of the present disclosure.

### DESCRIPTION OF THE EMBODIMENTS

### <<<<1. Modified Polybenzoxazole>>>>

It is preferred that a modified polybenzoxazole according to at least one embodiment of the present disclosure may be suitably used for forming a cleaning sheet that may be suitably used for a transfer member to be transferred in a substrate processing apparatus. However, the modified polybenzoxazole may also be used for any appropriate purpose other than the foregoing as long as the purpose is an application in which the effects of the present invention can be put to good use.

The modified polybenzoxazole according to at least one embodiment of the present disclosure has a storage modulus of elasticity at 1 Hz in the range of 0° C. to 100° C. of 200 MPa to 2,000 MPa. This means that the storage modulus of elasticity is adjusted within the narrow range of 200 MPa to 2,000 MPa over the wide temperature range of 0° C. to 100° C. Accordingly, the modified polybenzoxazole according to at least one embodiment of the present disclosure has a small temperature dependence of its modulus of elasticity.

The storage modulus of elasticity of the modified polybenzoxazole according to at least one embodiment of the present disclosure at 1 Hz in the range of from 0° C. to 100° C. is from 200 MPa to 2,000 MPa as described above, and is preferably from 500 MPa to 1,900 MPa, more preferably from 800 MPa to 1,800 MPa. When the storage modulus of elasticity of the modified polybenzoxazole according to at least one embodiment of the present disclosure at 1 Hz in the range of 0° C. to 100° C. falls within the ranges, the modified polybenzoxazole according to at least one embodiment of the present disclosure has a small temperature dependence of its modulus of elasticity, and can express an effect of showing a stable cleaning performance without being affected by the temperature condition of a stage to be cleaned (typically from 0° C. to 100° C.). In the case where the storage modulus of elasticity of the modified polybenzoxazole according to at least one embodiment of the present disclosure at 1 Hz in the range of 0° C. to 100° C. is less than 200 MPa, when the modified polybenzoxazole is applied to a cleaning sheet, the cleaning sheet shows a low modulus of elasticity, and hence may be transferred to the side to be cleaned, causing contamination to the contrary. In the case where the storage modulus of elasticity of the modified polybenzoxazole according to at least one embodiment of the present disclosure at 1 Hz in the range of 0° C. to 100° C. is more than 2,000 MPa, when the modified polybenzoxazole is applied to a cleaning sheet, the cleaning sheet may be insufficient in embedding property for particles to be collected, thereby being unable to sufficiently express cleaning performance. The storage modulus of elasticity at 1 Hz in the range of 0° C. to 100° C. is measured by a method to be described later.

The modified polybenzoxazole according to at least one embodiment of the present disclosure has a change ratio of the storage modulus of elasticity at 1 Hz in the range of 0° C. to 100° C. of preferably 50% or less, more preferably 40% or less, still more preferably 30% or less. When the change ratio of the storage modulus of elasticity of the modified polybenzoxazole according to at least one embodiment of the present disclosure at 1 Hz in the range of 0° C. to 100° C. falls within these ranges, the modified polybenzoxazole according to at least one embodiment of the present disclosure has an even smaller temperature dependence of its modulus of elasticity. When the change ratio of the storage modulus of elasticity of the modified polybenzoxazole according to at least one embodiment of the present disclosure at 1 Hz in the range of from 0° C. to 100° C. is so large as to deviate from the ranges, the cleaning sheet may show a low modulus of elasticity depending on the temperature condition of the stage to be cleaned (typically from 0° C. to 100° C.), and hence may stick to the side to be cleaned or may be transferred after peeling, causing contamination to the contrary. The change ratio of the storage modulus of elasticity at 1 Hz in the range of 0° C. to 100° C. is measured by a method to be described later.

The modified polybenzoxazole according to at least one embodiment of the present disclosure has a storage modulus of elasticity at 25° C. in the range of 0.001 Hz to 1 Hz of preferably from 200 MPa to 2,000 MPa, more preferably from 500 MPa to 1,900 MPa, still more preferably from 800 MPa to 1,800 MPa. When the storage modulus of elasticity of the modified polybenzoxazole according to at least one embodiment of the present disclosure at 25° C. in the range of 0.001 Hz to 1 Hz falls within the ranges, the modified polybenzoxazole according to at least one embodiment of the present disclosure has a small speed dependence of its modulus of elasticity, and can express an effect of showing a stable cleaning performance without being affected by the speed conditions of the stage to be cleaned, such as the speed of adsorption of the cleaning sheet to the stage and an adsorption retention time. In the case where the storage modulus of elasticity of the modified polybenzoxazole according to at least one embodiment of the present disclosure at 25° C. in the range of 0.001 Hz to 1 Hz is less than 200 MPa, when the modified polybenzoxazole is applied to a cleaning sheet, the cleaning sheet shows a low modulus of elasticity, and hence may be transferred to the side to be cleaned, causing contamination to the contrary. In the case where the storage modulus of elasticity of the modified polybenzoxazole according to at least one embodiment of the present disclosure at 25° C. in the range of 0.001 Hz to 1 Hz is more than 2,000 MPa, when the modified polybenzoxazole is applied to a cleaning sheet, the cleaning sheet may be insufficient in embedding property for particles to be collected, thereby being unable to sufficiently express cleaning performance. The storage modulus of elasticity at 25° C. in the range of 0.001 Hz to 1 Hz is measured by a method to be described later.

The modified polybenzoxazole according to at least one embodiment of the present disclosure has a change ratio of the storage modulus of elasticity at 25° C. in the range of 0.001 Hz to 1 Hz of preferably 50% or less, more preferably 40% or less, still more preferably 30% or less. When the change ratio of the storage modulus of elasticity of the modified polybenzoxazole according to at least one embodiment of the present disclosure at 25° C. in the range of 0.001 Hz to 1 Hz falls within these ranges, the modified polybenzoxazole according to at least one embodiment of the present disclosure can show a stable cleaning performance without being affected by the speed conditions of the stage to be cleaned, such as the speed of adsorption of the cleaning sheet to the stage and an adsorption retention time. When the change ratio of the storage modulus of elasticity of the modified polybenzoxazole according to at least one embodiment of the present disclosure at 25° C. in the range of 0.001 Hz to 1 Hz is so large as to deviate from the ranges, the cleaning sheet may show a low modulus of elasticity depending on the speed condition of the stage to be cleaned, and hence may stick to the side to be cleaned or may be transferred after peeling, causing contamination to the contrary. The change ratio of the storage modulus of elasticity at 25° C. in the range of 0.001 Hz to 1 Hz is measured by a method to be described later.

The modified polybenzoxazole according to at least one embodiment of the present disclosure has a Tg of preferably 100° C. or more, more preferably 120° C. or more, still more preferably 150° C. or more. When the Tg of the modified polybenzoxazole according to at least one embodiment of the present disclosure falls within these ranges, the modified polybenzoxazole according to at least one embodiment of the present disclosure can show a stable cleaning performance without being affected by the temperature condition of the stage to be cleaned (typically from 0° C. to 100° C.). When the Tg of the modified polybenzoxazole according to at least one embodiment of the present disclosure is so small as to deviate from the ranges, the cleaning sheet may show a low modulus of elasticity depending on the temperature condition of the stage to be cleaned (typically from 0° C. to 100° C.), and hence may stick to the side to be cleaned or may be transferred after peeling, causing contamination to the contrary. The Tg is measured by a method to be described later.

The modified polybenzoxazole according to at least one embodiment of the present disclosure has a TG at 1% weight loss according to TG-DTA analysis of preferably 350° C. or more. When the TG of the modified polybenzoxazole according to at least one embodiment of the present disclosure at 1% weight loss according to TG-DTA analysis falls within this range, the modified polybenzoxazole according to at least one embodiment of the present disclosure does not undergo thermal decomposition at the time of cleaning, and hence can suppress contamination in the apparatus due to outgassing. When the TG of the modified polybenzoxazole according to at least one embodiment of the present disclosure at 1% weight loss according to TG-DTA analysis is so large as to deviate from the range, thermal decomposition may occur at the time of cleaning to cause contamination in the apparatus due to outgassing. The TG at 1% weight loss according to TG-DTA analysis is measured by a method to be described later.

The modified polybenzoxazole according to at least one embodiment of the present disclosure has a TG at 5% weight loss according to TG-DTA analysis of preferably 400° C. or more, more preferably 420° C. or more. When the TG of the modified polybenzoxazole according to at least one embodiment of the present disclosure at 5% weight loss according to TG-DTA analysis falls within these ranges, the modified polybenzoxazole according to at least one embodiment of the present disclosure does not undergo thermal decomposition at the time of cleaning, and hence can suppress contamination in the apparatus due to outgassing. When the TG of the modified polybenzoxazole according to at least one embodiment of the present disclosure at 5% weight loss according to TG-DTA analysis is so large as to deviate from the ranges, thermal decomposition may occur at the time of cleaning to cause contamination in the apparatus due to outgassing. The TG at 5% weight loss according to TG-DTA analysis is measured by a method to be described later.

The modified polybenzoxazole according to at least one embodiment of the present disclosure has a water absorption ratio of preferably 0.1% or less. When the water absorption ratio of the modified polybenzoxazole according to at least one embodiment of the present disclosure falls within this range, the modified polybenzoxazole according to at least one embodiment of the present disclosure is little changed in characteristics, such as modulus of elasticity and adsorption force, during storage, and can also suppress outgassing from water when applied as a cleaning sheet in a reduced-pressure environment. When the water absorption ratio of the modified polybenzoxazole according to at least one embodiment of the present disclosure is so large as to deviate from the range, water absorption may cause changes in modulus of elasticity and adsorption force, or may cause outgassing from water during use in a reduced-pressure environment. The water absorption ratio is measured by a method to be described later.

The modified polybenzoxazole according to at least one embodiment of the present disclosure has an adsorption force at 25° C. of preferably from −0.8 μN to −0.3 μN, more preferably from −0.7 μN to −0.4 μN. When the adsorption force of the modified polybenzoxazole according to at least one embodiment of the present disclosure at 25° C. falls within these ranges, when applied to, for example, a cleaning sheet, the modified polybenzoxazole according to at least one embodiment of the present disclosure can express more excellent foreign matter-removing performance and more excellent contamination-suppressing performance. When the adsorption force of the modified polybenzoxazole according to at least one embodiment of the present disclosure at 25° C. is so small as to deviate from the ranges, when applied to, for example, a cleaning sheet, the modified polybenzoxazole may be unable to sufficiently express contamination-suppressing performance. When the adsorption force of the modified polybenzoxazole according to at least one embodiment of the present disclosure at 25° C. is so large as to deviate from the ranges, when applied to, for example, a cleaning sheet, the modified polybenzoxazole may be unable to sufficiently express foreign matter-removing performance. The adsorption force at 25° C. is measured by a method to be described later.

The modified polybenzoxazole according to at least one embodiment of the present disclosure has a benzoxazole ring structure and two or more amide groups.

The number of amide groups of the modified polybenzoxazole according to at least one embodiment of the present disclosure is preferably from 2 to 4, more preferably 2 or 3, still more preferably 2.

The two or more amide groups of the modified polybenzoxazole according to at least one embodiment of the present disclosure are preferably amide groups derived from a polyamine. The term “polyamine” as used herein means an amine having two or more amino groups. Each of the amino groups is, for example, at least one kind selected from the group consisting of a primary amino group, a secondary amino group, and a tertiary amino group, and is preferably at least one kind selected from the group consisting of a primary amino group, and a secondary amino group, more preferably a primary amino group because the effects of the present disclosure can be further expressed.

The polyamines may be used alone or as a mixture thereof.

Any appropriate polyamine may be adopted as the polyamine to the extent that the effects of the present disclosure are not impaired as long as the amine has two or more amino groups. Examples of the polyamine include a diamine compound having a polyether structure (hereinafter sometimes referred to as “PE diamine compound”), an aliphatic diamine, and an aromatic diamine because the effects of the present disclosure can be further expressed.

A preferred example of the polyamine is an aliphatic diamine represented by the following general formula (1) because the effects of the present disclosure can be still further expressed. When the aliphatic diamine represented by general formula (1) is adopted as the aliphatic diamine, the modified polybenzoxazole according to at least one embodiment of the present disclosure can have long-chain alkyl groups in a main chain and side chains thereof. The presence of the long-chain alkyl groups in the main chain and the side chains can increase free volume, and hence enables a reduction in elasticity, with the result that a contribution can be made to reducing the temperature dependence of the modulus of elasticity. In addition, when the modified polybenzoxazole according to at least one embodiment of the present disclosure has long-chain alkyl groups in side chains thereof, the side chains can be entangled with other molecular chains to construct a pseudo cross-linked structure, and hence enable an increase in Tg, with the result that a contribution can be made to reducing the temperature dependence of the modulus of elasticity.

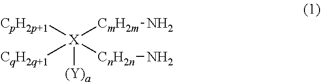

In general formula (1), “X” represents a hydrocarbon group of a y-membered ring structure, “y” represents from 4 to 8, a —CₘH₂ₘ—NH₂ group and a —CₙH₂ₙ—NH₂ group are each a long-chain alkylamino group bonded to X, “m” represents from 6 to 12, “n” represents from 6 to 12, a —CₚH₂ₚ₊₁ group and a —C_{q}H_{2q+1} group are each a long-chain alkyl group bonded to X, “p” represents from 6 to 12, “q” represents from 6 to 12, “Y” represents a long-chain alkyl group having 6 to 12 carbon atoms bonded to X, “a” represents the number of Ys bonded to X, “a” represents from 0 to 4, “a” Ys may represent long-chain alkyl groups identical to each other or may represent long-chain alkyl groups different from each other, Y is represented as a —CᵣH₂ᵣ₊₁ group, and “r” represents from 6 to 12. In addition, the long-chain alkyl groups may each contain a branched chain.

When the aliphatic diamine represented by general formula (1) is adopted as the polyamine, the aliphatic diamines each represented by the general formula (1) may be used alone or as a mixture thereof.

“y” in general formula (1) represents preferably from 5 to 7, more preferably 6 because the effects of the present disclosure can be further expressed. That is, a preferred embodiment of X in general formula (1) is a hydrocarbon group of a six-membered ring structure (cyclohexyl group).

“m” in general formula (1) represents preferably from 6 to 10, more preferably from 6 to 8, still more preferably 8 because the effects of the present disclosure can be further expressed.

“n” in general formula (1) represents preferably from 6 to 10, more preferably from 6 to 8, still more preferably 6 because the effects of the present disclosure can be further expressed.

“p” in general formula (1) represents preferably from 6 to 10, more preferably from 6 to 8, still more preferably 8 because the effects of the present disclosure can be further expressed.

“q” in general formula (1) represents preferably from 6 to 10, more preferably from 6 to 8, still more preferably 8 because the effects of the present disclosure can be further expressed.

“r” in general formula (1) represents preferably from 6 to 10, more preferably from 6 to 8, still more preferably 8 because the effects of the present disclosure can be further expressed.

“a” in general formula (1) represents preferably from 0 to 2, more preferably 0 because the effects of the present disclosure can be further expressed.

For the reason that the effects of the present disclosure can be further expressed, a preferred embodiment of the aliphatic diamine represented by the general formula (1) is as follows: “X” represents a hydrocarbon group of a six-membered ring structure (cyclohexyl group), “m” represents from 6 to 8, “n” represents from 6 to 8, “p” represents from 6 to 8, “q” represents from 6 to 8, and “a” represents 0, and a more preferred embodiment is as follows: X represents a hydrocarbon group of a six-membered ring structure (cyclohexyl group), “m” represents 8, “n” represents 6, “p” represents 8, and “q” represents 8.

A typical example of the aliphatic diamine represented by general formula (1) is a dimer diamine, and a commercially available example thereof is a product manufactured under the product name “Priamine 1075” by Croda.

The modified polybenzoxazole according to at least one embodiment of the present disclosure preferably contains a structural unit represented by the following general formula (2) and a structural unit represented by the following general formula (3). When the modified polybenzoxazole according to at least one embodiment of the present disclosure contains the structural unit represented by general formula (3), the modified polybenzoxazole can have long-chain alkyl groups in a main chain and side chains thereof. This can increase free volume, and hence enable a reduction in elasticity, with the result that a contribution can be made to reducing the temperature dependence of the modulus of elasticity. When the modified polybenzoxazole has long-chain alkyl groups in side chains thereof, the side chains can be entangled with other molecular chains to construct a pseudo cross-linked structure, and hence enable an increase in Tg, with the result that a contribution can be made to reducing the temperature dependence of the modulus of elasticity.

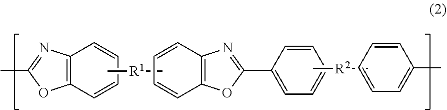

In general formula (2), R¹ and R² each independently represent CH₂, C(CH₃)₂, C(CF₃)₂, O, or a single bond.

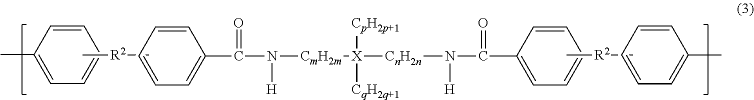

In general formula (3), R² represents CH₂, C(CH₃)₂, C(CF₃)₂, O, or a single bond, X represents a hydrocarbon group of a y-membered ring structure, “y” represents from 4 to 8, CₘH₂ₘ represents a long-chain alkylene chain, “m” represents from 6 to 12, CₙH₂ₙ represents a long-chain alkylene chain, “n” represents from 6 to 12, a —CₚH_{2p,1} group and a —C_{q}H_{2q+1} group are each a long-chain alkyl group bonded to X, “p” represents from 6 to 12, and “q” represents from 6 to 12. In addition, the long-chain alkylene chains and the long-chain alkyl groups may each contain a branched chain.

The number of kinds of the structural units each represented by general formula (2) that may be incorporated into the modified polybenzoxazole according to at least one embodiment of the present disclosure and the number of kinds of the structural units each represented by general formula (3) that may be incorporated thereinto may each be only one, or two or more.

“y” in general formula (3) represents preferably from 5 to 7, more preferably 6 because the effects of the present disclosure can be further expressed. That is, a preferred embodiment of X in general formula (3) is a hydrocarbon group of a six-membered ring structure (cyclohexyl group).

“m” in general formula (3) represents preferably from 6 to 10, more preferably from 6 to 8, still more preferably 8 because the effects of the present disclosure can be further expressed.

“n” in general formula (3) represents preferably from 6 to 10, more preferably from 6 to 8, still more preferably 6 because the effects of the present disclosure can be further expressed.

“p” in general formula (3) represents preferably from 6 to 10, more preferably from 6 to 8, still more preferably 8 because the effects of the present disclosure can be further expressed.

“q” in general formula (3) represents preferably from 6 to 10, more preferably from 6 to 8, still more preferably 8 because the effects of the present disclosure can be further expressed.

“r” in general formula (3) represents preferably from 6 to 10, more preferably from 6 to 8, still more preferably 8 because the effects of the present disclosure can be further expressed.

“a” in general formula (3) represents preferably from 0 to 2, more preferably 0 because the effects of the present disclosure can be further expressed.

For the reason that the effects of the present disclosure can be further expressed, a preferred embodiment of the structural unit represented by general formula (3) is as follows: X represents a hydrocarbon group of a six-membered ring structure (cyclohexyl group), “m” represents from 6 to 8, “n” represents from 6 to 8, “p” represents from 6 to 8, “q” represents from 6 to 8, and “a” represents 0, and a more preferred embodiment is as follows: X represents a hydrocarbon group of a six-membered ring structure (cyclohexyl group), “m” represents 8, “n” represents 6, “p” represents 8, and “q” represents 8.

The modified polybenzoxazole according to at least one embodiment of the present disclosure may be produced by any appropriate method to the extent that the effects of the present disclosure are not impaired. The modified polybenzoxazole according to at least one embodiment of the present disclosure is typically produced by allowing a bis(2-aminophenol) compound represented by the following general formula (4), a bis(chlorocarbonyl)diphenyl compound represented by the following general formula (5), and the aliphatic diamine represented by general formula (1) to react with each other.

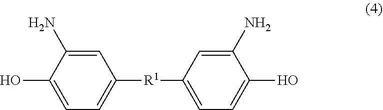

In general formula (4), R¹ represents CH₂, C(CH₃)₂, C(CF₃)₂, O, or a single bond.

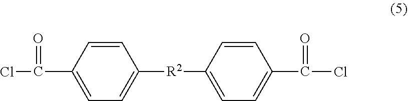

In general formula (5), R² represents CH₂, C(CH₃)₂, C(CF₃)₂, O, or a single bond.

When the modified polybenzoxazole according to at least one embodiment of the present disclosure is produced by allowing the bis(2-aminophenol) compound represented by general formula (4), the bis(chlorocarbonyl)diphenyl compound represented by general formula (5), and the aliphatic diamine represented by general formula (1) to react with each other, the blending ratio of the aliphatic diamine represented by general formula (1) is preferably from 6 mol % to 49 mol %, more preferably from 7 mol % to 47 mol %, still more preferably from 8 mol % to 45 mol %, particularly preferably from 9 mol % to 42 mol %, most preferably from 10 mol % to 40 mol % in terms of molar ratio with respect to 100 mol % of the total amount of the amines, that is, the total amount of the bis(2-aminophenol) compound represented by general formula (4) and the aliphatic diamine represented by general formula (1).

When the modified polybenzoxazole according to at least one embodiment of the present disclosure is produced by allowing the bis(2-aminophenol) compound represented by general formula (4), the bis(chlorocarbonyl)diphenyl compound represented by the general formula (5), and the aliphatic diamine represented by the general formula (1) to react with each other, the blending ratio of the bis(chlorocarbonyl)diphenyl compound represented by general formula (5) with respect to the total amount of the aliphatic diamine represented by general formula (1) and the bis(2-aminophenol) compound represented by general formula (4), that is, the total amount of the amines is preferably from 70 mol % to 130 mol %, more preferably from 80 mol % to 120 mol %, still more preferably from 90 mol % to 110 mol % of the bis(chlorocarbonyl)diphenyl compound represented by the general formula (5) in terms of molar ratio with respect to 100 mol % of the total amount of the aliphatic diamine represented by general formula (1) and the bis(2-aminophenol) compound represented by general formula (4).

### ««2. Modified Polybenzoxazole Sheet>>»

A modified polybenzoxazole sheet according to at least one embodiment of the present disclosure contains the modified polybenzoxazole according to at least one embodiment of the present disclosure. The content of the modified polybenzoxazole according to at least one embodiment of the present disclosure in the modified polybenzoxazole sheet according to at least one embodiment of the present disclosure is preferably from 50 wt % to 100 wt %, more preferably from 70 wt % to 100 wt %, still more preferably from 90 wt % to 100 wt %, particularly preferably from 95 wt % to 100 wt %, most preferably substantially 100 wt %.

Any appropriate other component may be incorporated into the modified polybenzoxazole sheet according to at least one embodiment of the present disclosure to the extent that the effects of the present disclosure are not impaired. Examples of such other component include a heat-resistant resin except polybenzoxazole, a surfactant, a plasticizer, an antioxidant, a conductivity providing agent, a UV absorber, and a photostabilizer.

The modified polybenzoxazole sheet according to at least one embodiment of the present disclosure is typically obtained by forming the modified polybenzoxazole according to at least one embodiment of the present disclosure into a sheet shape. The modified polybenzoxazole sheet according to at least one embodiment of the present disclosure is typically formed by applying a varnish of the modified polybenzoxazole according to at least one embodiment of the present disclosure onto any appropriate base material and removing a solvent through heating.

Any appropriate thickness may be adopted as the thickness of the modified polybenzoxazole sheet according to at least one embodiment of the present disclosure in accordance with its intended use.

When the modified polybenzoxazole sheet according to at least one embodiment of the present disclosure contains the modified polybenzoxazole according to at least one embodiment of the present disclosure as a main component, that is, when the content of the modified polybenzoxazole according to at least one embodiment of the present disclosure in the modified polybenzoxazole sheet according to at least one embodiment of the present disclosure is preferably from 90 wt % to 100 wt %, more preferably from 93 wt % to 100 wt %, still more preferably from 95 wt % to 100 wt %, particularly preferably from 98 wt % to 100 wt %, most preferably substantially 100 wt %, the modified polybenzoxazole sheet shows characteristics similar to those of the modified polybenzoxazole according to at least one embodiment of the present disclosure, and preferably shows a storage modulus of elasticity at 1 Hz in the range of from 0° C. to 100° C., a change ratio of the storage modulus of elasticity at 1 Hz in the range of 0° C. to 100° C., a change ratio of a storage modulus of elasticity at 25° C. in the range of 0.001 Hz to 1 Hz, a Tg, a TG at 1% weight loss according to TG-DTA analysis, a TG at 5% weight loss according to TG-DTA analysis, a water absorption ratio, and an adsorption force at 25° C. that are similar to those of the modified polybenzoxazole according to at least one embodiment of the present disclosure.

### <<<<3. Cleaning Sheet>>>>

A cleaning sheet according to at least one embodiment of the present disclosure includes a cleaning layer, wherein the cleaning layer is the modified polybenzoxazole sheet according to at least one embodiment of the present disclosure.

The cleaning sheet according to at least one embodiment of the present disclosure includes a cleaning layer. The cleaning sheet according to at least one embodiment of the present disclosure may include only the cleaning layer, or may include any other layer.

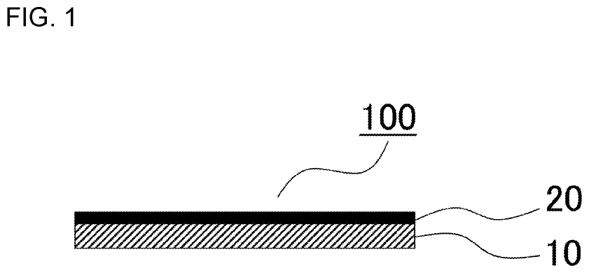

FIG. 1 is a schematic cross-sectional view for illustrating a cleaning sheet according to at least one embodiment of the present disclosure. In FIG. 1, a cleaning sheet 100 includes a cleaning layer 10 and a protective film 20. The protective film 20 may be arranged for the purpose of, for example, protecting the cleaning layer 10, and may be omitted in accordance with purposes. That is, the cleaning sheet according to at least one embodiment of the present disclosure may include only the cleaning layer 10.

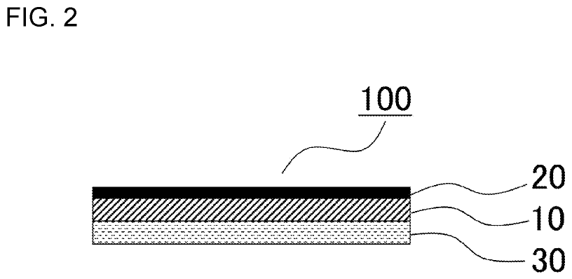

FIG. 2 is a schematic cross-sectional view for illustrating a cleaning sheet according to at least one embodiment of the present disclosure. In FIG. 2, the cleaning sheet 100 includes the protective film 20, the cleaning layer 10, and a pressure-sensitive adhesive layer 30. The protective film 20 may be arranged for the purpose of, for example, protecting the cleaning layer 10, and may be omitted in accordance with purposes.

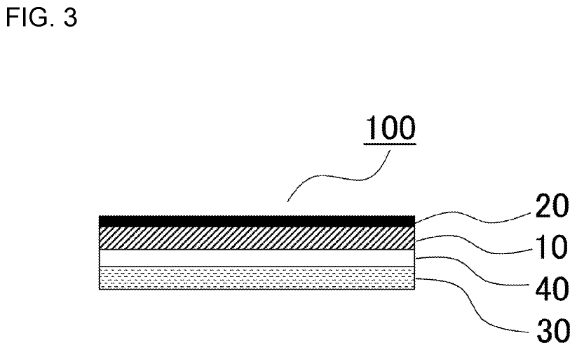

FIG. 3 is a schematic cross-sectional view for illustrating a cleaning sheet according to at least one embodiment of the present disclosure. In FIG. 3, the cleaning sheet 100 includes the protective film 20, the cleaning layer 10, a support 40, and the pressure-sensitive adhesive layer 30. The protective film 20 may be arranged for the purpose of, for example, protecting the cleaning layer 10, and may be omitted in accordance with purposes.

Any appropriate thickness may be adopted as the thickness of the cleaning sheet according to at least one embodiment of the present disclosure in accordance with its configuration (in particular, for example, whether or not the sheet includes a support or a pressure-sensitive adhesive layer, and how thick the support or the layer is).

The cleaning sheet according to at least one embodiment of the present disclosure is preferably excellent in heat resistance, thereby being able to be sufficiently used even under a high-temperature environment. Such high-temperature environment is preferably 150° C. or more, more preferably 200° C. or more, still more preferably 250° C. or more, still more preferably 300° C. or more, particularly preferably 350° C. or more.

The cleaning layer is the modified polybenzoxazole sheet according to at least one embodiment of the present disclosure, and hence shows characteristics similar to those of the modified polybenzoxazole sheet according to at least one embodiment of the present disclosure, and preferably shows a storage modulus of elasticity at 1 Hz in the range of 0° C. to 100° C., a change ratio of the storage modulus of elasticity at 1 Hz in the range of 0° C. to 100° C., a change ratio of a storage modulus of elasticity at 25° C. in the range of 0.001 Hz to 1 Hz, a Tg, a TG at 1% weight loss according to TG-DTA analysis, a TG at 5% weight loss according to TG-DTA analysis, a water absorption ratio, and an adsorption force at 25° C. that are similar to those of the modified polybenzoxazole sheet according to at least one embodiment of the present disclosure.

The thickness of the cleaning layer is preferably from 1 μm to 500 μm, more preferably from 3 μm to 100 μm, still more preferably from 5 μm to 50 μm. When the thickness of the cleaning layer falls within the ranges, a cleaning sheet that may be suitably used for a transfer member to be transferred in a substrate processing apparatus can be provided.

The cleaning layer is substantially free of a pressure-sensitive adhesive strength. More specifically, for example, a cleaning layer formed of an adherent material and a cleaning layer formed by fixing a pressure-sensitive adhesive tape are excluded from the cleaning layer in at least one embodiment of the present disclosure. When the cleaning sheet according to at least one embodiment of the present disclosure includes a cleaning layer substantially having a pressure-sensitive adhesive strength, the cleaning layer and for example, a transfer device in a substrate processing apparatus may be bonded to each other so strongly in a contact portion therebetween that the layer and the device are not separated from each other. As a result, there may arise a problem in that a substrate cannot be securely transferred and a problem in that the transfer device is damaged.

As described above, the cleaning layer is substantially free of a pressure-sensitive adhesive strength. Specifically, the layer has a 180° peeling pressure-sensitive adhesive strength A of preferably less than 0.20 N/10 mm, more preferably from 0.01 N/10 mm to 0.10 N/10 mm, which is specified in Japan Industrial Standards JIS-Z-0237 with respect to the mirror surface of a silicon wafer. When the 180° peeling pressure-sensitive adhesive strength A of the cleaning layer, which is specified in JIS-Z-0237 with respect to the mirror surface of the silicon wafer, falls within such ranges, the cleaning layer is substantially free of a pressure-sensitive adhesive strength, and hence the pressure-sensitive adhesive property of a contact portion between the cleaning layer and for example, a transfer device in a substrate processing apparatus can be reduced. As a result, a substrate can be securely transferred, and the transfer device may be hardly damaged.

The cleaning layer has a 180° peeling pressure-sensitive adhesive strength B of preferably 10 N/10 mm or more, more preferably 15 N/10 mm or more, still more preferably 20 N/10 mm or more, particularly preferably 25 N/10 mm or more, most preferably 30 N/10 mm or more, which is specified in JIS-Z-0237 with respect to the mirror surface of a dummy wafer. When the 180° peeling pressure-sensitive adhesive strength B of the cleaning layer, which is specified in JIS-Z-0237 with respect to the mirror surface of the dummy wafer, falls within the ranges, for example, adhesiveness between the cleaning layer and a transfer member such as the dummy wafer becomes higher, and hence the cleaning layer hardly peels from the transfer member such as the dummy wafer during cleaning.

The 180° peeling pressure-sensitive adhesive strength B of the cleaning layer, which is specified in JIS-Z-0237 with respect to the mirror surface of the dummy wafer, may be measured, for example, as follows: the cleaning layer is formed on the mirror surface of a silicon wafer serving as the dummy wafer, and its peeling pressure-sensitive adhesive strength is measured in conformity with JIS-Z-0237.

The cleaning sheet according to at least one embodiment of the present disclosure may include a support. The support may be a single layer, or may be a multilayered body.

Any appropriate thickness may be adopted as the thickness of the support to the extent that the effects of the present disclosure are not impaired. Such thickness is preferably 500 μm or less, more preferably from 1 μm to 400 μm, still more preferably from 1 μm to 300 μm, particularly preferably from 1 μm to 200 μm, most preferably from 1 μm to 100 μm.

Any appropriate support may be adopted as the support to the extent that the effects of the present disclosure are not impaired. Examples of such support include films made of plastic, engineering plastic, and super engineering plastic. Specific examples of the plastic, the engineering plastic, and the super engineering plastic include polyimide, polyethylene, polyethylene terephthalate, acetyl cellulose, polycarbonate, polypropylene, and polyamide.

Various physical properties such as a molecular weight of a material for the support may be appropriately selected in accordance with purposes.

A method of forming the support may be appropriately selected in accordance with purposes.

The surface of the support may be subjected to conventional surface treatment, for example, chemical or physical treatment, such as chromic acid treatment, ozone exposure, flame exposure, high-pressure shock exposure, and ionizing radiation treatment, or coating treatment with an undercoating agent, in order to enhance its adhesiveness with respect to an adjacent layer, retention property, and the like.

The cleaning sheet according to at least one embodiment of the present disclosure may include a pressure-sensitive adhesive layer. Any appropriate material may be adopted as a material for such pressure-sensitive adhesive layer to the extent that the effects of the present disclosure are not impaired. For example, an acrylic pressure-sensitive adhesive, a silicone-based pressure-sensitive adhesive, a rubber-based pressure-sensitive adhesive, or a urethane-based pressure-sensitive adhesive may be adopted as the material for such pressure-sensitive adhesive layer.

The pressure-sensitive adhesive layer is arranged for, for example, bonding the cleaning sheet to the mirror surface of a dummy wafer. Thus, the cleaning sheet according to at least one embodiment of the present disclosure is bonded to the dummy wafer serving as a transfer member, and hence a transfer member provided with a cleaning function according to at least one embodiment of the present disclosure can be obtained.

The pressure-sensitive adhesive layer has a 180° peeling pressure-sensitive adhesive strength C of preferably 10 N/10 mm or more, more preferably 15 N/10 mm or more, still more preferably 20 N/10 mm or more, particularly preferably 25 N/10 mm or more, most preferably 30 N/10 mm or more, which is specified in JIS-Z-0237 with respect to the mirror surface of a dummy wafer. When the 180° peeling pressure-sensitive adhesive strength C of the pressure-sensitive adhesive layer, which is specified in JIS-Z-0237 with respect to the mirror surface of the dummy wafer, falls within the ranges, for example, an adhesive strength between the pressure-sensitive adhesive layer and the dummy wafer becomes higher, and hence the cleaning sheet hardly peels from the dummy wafer during cleaning.

The thickness of the pressure-sensitive adhesive layer is preferably from 1 μm to 200 μm, more preferably from 2 μm to 100 μm, still more preferably from 3 μm to 80 μm, particularly preferably from 4 μm to 60 μm, most preferably from 5 μm to 50 μm.

The cleaning sheet according to at least one embodiment of the present disclosure may include a protective film for protecting, for example, the cleaning layer, the support, or the pressure-sensitive adhesive layer. The protective film may be peeled in an appropriate stage.

Any appropriate film may be adopted as the protective film to the extent that the effects of the present disclosure are not impaired. Examples of a material for such film include polyolefins, such as polyethylene, polypropylene, polybutene, polybutadiene, and polymethylpentene, polyvinyl chloride, a vinyl chloride copolymer, polyethylene terephthalate, polybutylene terephthalate, polyurethane, an ethylene vinyl acetate copolymer, an ionomer resin, an ethylene-(meth)acrylic acid copolymer, an ethylene-(meth)acrylic acid ester copolymer, polystyrene, polycarbonate, polyimide, and a fluorine resin.

The protective film may be subjected to any appropriate peeling treatment to the extent that the effects of the present disclosure are not impaired. The peeling treatment is typically performed with a peeling agent. Examples of the peeling agent may include a silicone-based peeling agent, a long-chain alkyl-based peeling agent, a fluorine-based peeling agent, a fatty acid amide-based peeling agent, and a silica-based peeling agent.

The protective film preferably has a thickness of from 1 μm to 100 μm.

A method of forming the protective film is appropriately selected in accordance with purposes, and the film may be formed by, for example, an injection molding method, an extrusion molding method, or a blow molding method.

Any appropriate method may be adopted as a method of producing the cleaning sheet according to at least one embodiment of the present disclosure to the extent that the effects of the present disclosure are not impaired. Examples of such production method include: (1) a method including casting a varnish solution of the modified polybenzoxazole according to at least one embodiment of the present disclosure onto a support, uniformly forming the solution into a film with a spin coater or the like, and then heating the film to directly form the cleaning layer on the support, and (2) a method including forming a laminate formed of a release liner and a pressure-sensitive adhesive film serving as a constituent material for a label and a reinforcing portion (a product obtained by arranging the cleaning layer on one surface of a label support and a typical pressure-sensitive adhesive layer on the other surface thereof) by, for example, a method including bonding the pressure-sensitive adhesive film onto the release liner, then punching only the pressure-sensitive adhesive film of the laminate into the respective shapes of the label and/or the reinforcing portion simultaneously or separately, and peeling and removing an unnecessary pressure-sensitive adhesive film from the release liner.

<<<<4. Transfer Member Provided with Cleaning Function>>>>

The transfer member provided with a cleaning function according to at least one embodiment of the present disclosure includes the cleaning sheet according to at least one embodiment of the present disclosure and a transfer member.

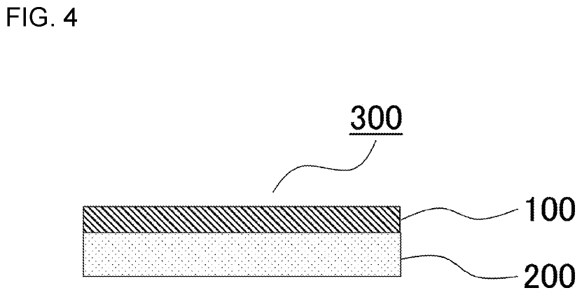

FIG. 4 is a schematic cross-sectional view for illustrating the transfer member provided with a cleaning function according to at least one embodiment of the present disclosure. In FIG. 4, a transfer member 300 provided with a cleaning function includes the cleaning sheet 100 and a transfer member 200. When the cleaning sheet 100 includes a pressure-sensitive adhesive layer, the outermost layer on the transfer member 200 side of the cleaning sheet 100 is preferably the pressure-sensitive adhesive layer.

Any appropriate transfer member may be adopted as the transfer member to the extent that the effects of the present disclosure are not impaired. Examples of such transfer member include a semiconductor wafer (e.g., a silicon wafer), a substrate for a flat panel display, such as an LCD or a PDP, a compact disc, and a MR head. Of those transfer members, a semiconductor wafer (e.g., a silicon wafer) is typically given as an example of the transfer member when the transfer member is intended to clean a device for transferring a wafer in a substrate processing apparatus.

### EXAMPLES

The present disclosure is more specifically described below by way of Examples and Comparative Examples. However, the present disclosure is by no means limited thereto. In the following description, the terms “part(s)” and “%” are by weight unless otherwise stated.

### <Measurement of Storage Modulus of Elasticity at 1 Hz in Range of 0° C. to 100° C.>

A storage modulus of elasticity was measured using a solid viscoelasticity-measuring apparatus (model: RSAG-2, manufactured by TA Instruments Japan Inc.). Specifically, a test piece having a length of 30 mm (measurement length) and a width of 10 mm was cut out, and the storage modulus of elasticity of the test piece was measured using the solid viscoelasticity-measuring apparatus (model: RSAG-2, manufactured by TA Instruments Japan Inc.) under the conditions of a frequency of 1 Hz, a temperature increase rate of 10° C./min, and a chuck-to-chuck distance of 10 mm in the temperature range of 0° C. to 100° C.

### <Measurement of Change Ratio of Storage Modulus of Elasticity at 1 Hz in Range of 0° C. to 100° C.>

In the measurement of the storage modulus of elasticity at 1 Hz in the range of 0° C. to 100° C., values at 0° C. and 100° C. were read, and a change ratio was calculated by the following equation.

Change ratio (%)=[(storage modulus of elasticity at 100° C.−storage modulus of elasticity at 0° C.)/storage modulus of elasticity at 0° C.]×100

### <Measurement of Storage Modulus of Elasticity at 25° C. in Range of 0.001 Hz to 1 Hz>

A storage modulus of elasticity was measured using a solid viscoelasticity-measuring apparatus (model: RSAG-2, manufactured by TA Instruments Japan Inc.). Specifically, a test piece having a length of 30 mm (measurement length) and a width of 10 mm was cut out, and a frequency-temperature dispersion test was performed using the solid viscoelasticity-measuring apparatus (model: RSAG-2, manufactured by TA Instruments Japan Inc.) under the condition of a chuck-to-chuck distance of 10 mm, in increments of 5° C. in the temperature range of 0° C. to 100° C., and under the condition of a frequency of 0.1 Hz to 10 Hz. Then, through use of the measurement results, a shift factor was determined using the WLF equation (in conformity with Experimental Equation (13) described in JIS K 6394). A frequency dependence curve at each measurement temperature was shifted in accordance with the shift factor to prepare a master curve at a reference temperature of 25° C., and a storage modulus of elasticity at 0.001 Hz to 1 Hz was calculated.

### <Measurement of Change Ratio of Storage Modulus of Elasticity at 25° C. in Range of 0.001 Hz to 1 Hz>

In the measurement of the storage modulus of elasticity at 25° C. in the range of 0.001 Hz to 1 Hz, values at 0.001 Hz and 1 Hz were read, and a change ratio was calculated by the following equation.

Change ratio (%)=[(storage modulus of elasticity at 0.001Hz−storage modulus of elasticity at 1Hz)/storage modulus of elasticity at 1Hz]×100

### <Measurement of Tg>

The maximum value of tanδ obtained simultaneously with the measurement of the storage modulus of elasticity at 1 Hz in the range of 0° C. to 100° C. was read as a Tg.

### <Measurement of TG at 1% Weight Loss and 5% Weight Loss by TG-DTA Analysis>

Measurement was performed using a thermal analyzer (TG-DTA) “Thermo plus TG8120” (manufactured by Rigaku Corporation). The amount of thermal weight loss of a test piece having a length of 30 mm (measurement length) and a width of 10 mm was measured at a temperature increase rate of 10° C./min in the temperature range of from 25° C. to 500° C.

### <Measurement of Water Absorption Ratio>

The weight of a modified polybenzoxazole sheet (thickness: 20 μm) formed over the entire surface of a wafer (diameter: 150 mm/thickness: 720 um) was measured. After that, the whole was left at rest in an environment at 85° C. and 85% RH for 72 hours, the weight was measured again, and a water absorption ratio was calculated from a change in the weight.

Water absorption ratio (%)=[(weight after water absorption−weight before water absorption)/weight before water absorption]×100

### <Measurement of Adsorption Force at 25° C.>

Measurement was performed with a nanoindenter at a frequency of 100 Hz, an indentation depth of 100 nm, a measurement sample size of 1.0 cm×1.0 cm, and an amplitude of 2 nm. Specifically, measurement was performed under the following conditions, and the minimum load of an unloading curve in the resultant load-displacement curve was defined as an adsorption force.

### (Measurement Apparatus and Measurement Conditions)

Apparatus: Tribo Indenter manufactured by Hysitron Inc.
Indenter used: Berkovich (triangular pyramid-shaped)
Measurement method: single indentation measurement
Indentation depth setting: 100 nm
Frequency: 100 Hz
Amplitude: 2 nm
Sample size: 1 cm×1 cm

### Example 1

### (Production of Varnish of Modified Polybenzoxazole)

12.0 Grams of 4,4′-(hexafluoroisopropylidene)bis(2-aminophenol), 8.0 g of pyridine, and 100 g of N-methyl pyrrolidone were loaded into a separable flask mounted with a stirring device, and the mixture was stirred at room temperature until 4,4′-(hexafluoroisopropylidene)bis(2-aminophenol) and “Priamine 1075” were completely dissolved. After that, 7.5 g of trimethylchlorosilane was dropped into the flask over 10 minutes, and the mixture was stirred for 60 minutes at room temperature. 2.0 Grams of a polyamine (manufactured by Croda, product name: “Priamine 1075”, dimer diamine) was added to the flask, and the mixture was stirred for 3 minutes. After that, 11.0 g of 4,4′-bis(chlorocarbonyl)diphenyl ether was slowly added to the flask over 30 minutes, and the mixture was stirred at room temperature for 2 hours.

The resultant synthesized liquid was dropped into 2 L of ion-exchanged water, and the resultant precipitate was dried at 100° C. for 24 hours. A 4-fold amount of N-methyl-2-pyrrolidone was added to the precipitate after the drying to redissolve the precipitate. Thus, a varnish of a modified polybenzoxazole (1) was obtained.

(Production and Evaluation of Transfer Member Provided with Cleaning Function Including Cleaning Layer)

The resultant varnish of the modified polybenzoxazole (1) was applied onto the mirror surface of an 8-inch silicon wafer by spin coating. The varnish was heated at 120° C. for 10 minutes so that N-methyl-2-pyrrolidone was removed. After that, the residue was heated under a vacuum at 300° C. for 2 hours. Thus, a transfer member (1) provided with a cleaning function including a cleaning layer (1) having a thickness of 20 μm was obtained.

The results of the various evaluations are shown in Table 1.

### Example 2

A modified polybenzoxazole (2) and a transfer member (2) provided with a cleaning function including a cleaning layer (2) having a thickness of 20 μm were obtained in the same manner as in Example 1 except that the usage amount of 4,4′-(hexafluoroisopropylidene)bis(2-aminophenol) was changed to 11.0 g, and the usage amount of the polyamine (manufactured by Croda, product name: “Priamine 1075”, dimer diamine) was changed to 4.0 g.

The results of the various evaluations are shown in Table 1.

### Example 3

A modified polybenzoxazole (3) and a transfer member (3) provided with a cleaning function including a cleaning layer (3) having a thickness of 20 μm were obtained in the same manner as in Example 1 except that the usage amount of 4,4′-(hexafluoroisopropylidene)bis(2-aminophenol) was changed to 9.5 g, and the usage amount of the polyamine (manufactured by Croda, product name: “Priamine 1075”, dimer diamine) was changed to 6.0 g.

The results of the various evaluations are shown in Table 1.

### Example 4

A modified polybenzoxazole (4) and a transfer member (4) provided with a cleaning function including a cleaning layer (4) having a thickness of 20 μm were obtained in the same manner as in Example 1 except that the usage amount of 4,4′-(hexafluoroisopropylidene)bis(2-aminophenol) was changed to 8.0 g, and the usage amount of the polyamine (manufactured by Croda, product name: “Priamine 1075”, dimer diamine) was changed to 8.0 g.

The results of the various evaluations are shown in Table 1.

### Example 5

A modified polybenzoxazole (5) and a transfer member (5) provided with a cleaning function including a cleaning layer (5) having a thickness of 20 μm were obtained in the same manner as in Example 1 except that the usage amount of 4,4′-(hexafluoroisopropylidene)bis(2-aminophenol) was changed to 10.9 g, and 7.7 g of a polyamine (manufactured by Huntsman Corporation, product name: “ELASTAMINE RT-1000”, PE diamine, H₂N—CH(CH₃)—CH₂—(O—CH(CH₃)—CH₂)₂—(O—CH₂CH₂CH₂CH₂)₉—(O—CH₂—CH(CH₃))₃—NH₂) was used in place of the polyamine (manufactured by Croda, product name: “Priamine 1075”, dimer diamine).

The results of the various evaluations are shown in Table 1.

### Comparative Example 1

A modified polybenzoxazole (C1) and a transfer member (C1) provided with a cleaning function including a cleaning layer (C1) having a thickness of 20 μm were obtained in the same manner as in Example 1 except that the usage amount of 4,4′-(hexafluoroisopropylidene)bis(2-aminophenol) was changed to 8.7 g, and 13.2 g of a polyamine (manufactured by Huntsman Corporation, product name: “ELASTAMINE RT-1000”, H₂N—CH(CH₃)—CH₂—(O—CH(CH₃)—CH₂)₂—(O—CH₂CH₂CH₂CH₂)₉—(O—CH₂— CH(CH₃))₃—NH₂) was used in place of the polyamine (manufactured by Croda, product name: “Priamine 1075”, dimer diamine).

The results of the various evaluations are shown in Table 1.

### Comparative Example 2

A modified polybenzoxazole (C2) and a transfer member (C2) provided with a cleaning function including a cleaning layer (C2) having a thickness of 20 μm were obtained in the same manner as in Example 1 except that the usage amount of 4,4′-(hexafluoroisopropylidene)bis(2-aminophenol) was changed to 11.6 g, and 5.7 g of a polyamine (manufactured by Huntsman Corporation, product name: “ELASTAMINE RT-1000”, H₂N—CH(CH₃)—CH₂—(O—CH(CH₃)—CH₂)₂—(O—CH₂CH₂CH₂CH₂)₉—(O—CH₂—CH(CH₃))₃—NH₂) was used in place of the polyamine (manufactured by Croda, product name: “Priamine 1075”, dimer diamine).

The results of the various evaluations are shown in Table 1.

### Comparative Example 3

A modified polybenzoxazole (C3) and a transfer member (C3) provided with a cleaning function including a cleaning layer (C3) having a thickness of 20 μm were obtained in the same manner as in Example 1 except that the usage amount of 4,4′-(hexafluoroisopropylidene)bis(2-aminophenol) was changed to 13.0 g, and the usage amount of the polyamine (manufactured by Croda, product name: “Priamine 1075”, dimer diamine) was changed to 1.0 g.

The results of the various evaluations are shown in Table 1.

### Comparative Example 4

A modified polybenzoxazole (C4) and a transfer member (C4) provided with a cleaning function including a cleaning layer (C4) having a thickness of 20 μm were obtained in the same manner as in Example 1 except that the usage amount of 4,4′-(hexafluoroisopropylidene)bis(2-aminophenol) was changed to 6.5 g, and the usage amount of the polyamine (manufactured by Croda, product name: “Priamine 1075”, dimer diamine) was changed to 9.8 g.

The results of the various evaluations are shown in Table 1.

### Comparative Example 5

A modified polybenzoxazole (C5) and a transfer member (C5) provided with a cleaning function including a cleaning layer (C5) having a thickness of 20 μm were obtained in the same manner as in Example 1 except that 4,4′-(hexafluoroisopropylidene)bis(2-aminophenol) and trimethylchlorosilane were not used, and the usage amount of the polyamine (manufactured by Croda, product name: “Priamine 1075”, dimer diamine) was changed to 20 g.

The results of the various evaluations are shown in Table 1.

TABLE 1

| | | | | | | | Compar- |
|---|---|---|---|---|---|---|---|
| | | Exam- | Exam- | Exam- | Exam- | Exam- | ative |
| | | ple 1 | ple 2 | ple 3 | ple 4 | ple 5 | Example 1 |
| Raw material | (a)Bis(chlorocarbonyl)diphe- | 4,4′-Bis(chlorocarbonyl)diphenyl ether | | | | | |
| | nyl compound | | | | | | |
| | (b)Bis(2-aminophenol) | 4,4′-(Hexafluoroisopropylidene)bis(2-aminophenol) | | | | | |
| | compound | | | | | | |
| | (c)Polyamine | Priamine | Priamine | Priamine | Priamine | RT-1000 | RT-1000 |
| | | 1075 | 1075 | 1075 | 1075 | | |
| | Addition amount (mol %) | 10 | 20 | 30 | 40 | 20 | 35 |
| | of (c) (with respect to | | | | | | |
| | amines [(b) + (c)]) | | | | | | |
| Characteristics | Water absorption ratio | 0 | 0 | 0 | 0 | 0.2 | 0.3 |
| | (%) | | | | | | |
| | Tg (° C.) | 248 | 245 | 193 | 148 | 146 | 80 |
| | TG (° C.) at 1% weight | 380 | 380 | 380 | 380 | 344 | 344 |
| | loss | | | | | | |
| | TG (° C.) at 5% weight | 435 | 435 | 430 | 430 | 380 | 380 |
| | loss | | | | | | |
| | Adsorption force (μN) | −0.4 | −0.45 | −0.58 | −0.62 | −0.41 | −0.72 |
| | at 25° C. | | | | | | |
| Storage modulus | Storage modulus of | 1,650 | 1,320 | 1,281 | 1,210 | 1,880 | 1,000 |
| of elasticity | elasticity at 0° C. | | | | | | |
| at 1 Hz in | (1 Hz) | | | | | | |
| range of from | Storage modulus of | 1,150 | 1,040 | 1,011 | 980 | 400 | 0.004 |
| 0° C. to | elasticity at 100° C. | | | | | | |
| 100° C. | (1 Hz) | | | | | | |
| | Change ratio (%) of | −30 | −21 | −21 | −19 | −79 | −100 |
| | storage modulus of | | | | | | |
| | elasticity at 1 Hz in | | | | | | |
| | range of from 0° C. to | | | | | | |
| | 100° C. | | | | | | |
| Storage modulus | Storage modulus of | 1,988 | 1,872 | 1,700 | 1,484 | 837 | 609 |
| of elasticity | elasticity at 1 Hz | | | | | | |
| at 25° C. in | (25° C.) | | | | | | |
| range of from | Storage modulus of | 1,833 | 1,773 | 1,582 | 1,339 | 613 | 407 |
| 0.001 Hz to | elasticity at 0.01 Hz | | | | | | |
| 1 Hz | (25° C.) | | | | | | |
| | Storage modulus of | 1,782 | 1,670 | 1,400 | 1,200 | 422 | 183 |
| | elasticity at 0.001 Hz | | | | | | |
| | (25° C.) | | | | | | |
| | Change ratio (%) of | −10 | −10 | −18 | −19 | −50 | −70 |
| | storage modulus of | | | | | | |
| | elasticity at 25° C. in | | | | | | |
| | range of from 0.001 Hz | | | | | | |
| | to 1 Hz | | | | | | |

| | | Compar- | Compar- | Compar- | Compar- |
|---|---|---|---|---|---|
| | | ative | ative | ative | ative |
| | | Example 2 | Example 3 | Example 4 | Example 5 |
| Raw material | (a)Bis(chlorocarbonyl)diph- | 4,4′-Bis(chlorocarbonyl)diphenyl ether | | | |
| | enyl compound | | | | |
| | (b)Bis(2-aminophenol) | 4,4′-(Hexafluoroisopropylidene)bis(2-aminophenol) | | | |
| | compound | | | | |
| | (c)Polyamine | RT-1000 | Priamine | Priamine | Priamine |
| | | | 1075 | 1075 | 1075 |
| | Addition amount (mol %) | 15 | 5 | 50 | 100 |
| | of (c) (with respect to | | | | |
| | amines [(b) + (c)]) | | | | |
| Characteristics | Water absorption ratio | 0.2 | 0 | 0 | 0.1 |
| | (%) | | | | |
| | Tg (° C.) | 175 | 250 | 120 | 60 |
| | TG (° C.) at 1% weight | 344 | 380 | 380 | 399 |
| | loss | | | | |
| | TG (° C.) at 5% weight | 380 | 435 | 430 | 435 |
| | loss | | | | |
| | Adsorption force (μN) | −0.36 | −0.35 | −0.76 | −1.4 |
| | at 25° C. | | | | |
| Storage modulus | Storage modulus of | 2,230 | 2,200 | 1,230 | 871 |
| of elasticity | elasticity at 0° C. | | | | |
| at 1 Hz in | (1 Hz) | | | | |
| range of from | Storage modulus of | 1,370 | 1,540 | 187 | 7 |
| 0° C. to | elasticity at 100° C. | | | | |
| 100° C. | (1 Hz) | | | | |
| | Change ratio (%) of | −39 | −30 | −85 | −99 |
| | storage modulus of | | | | |
| | elasticity at 1 Hz in | | | | |
| | range of from 0° C. to | | | | |
| | 100° C. | | | | |
| Storage modulus | Storage modulus of | 2,339 | 2,543 | 1,390 | 636 |
| of elasticity | elasticity at 1 Hz | | | | |
| at 25° C. in | (25° C.) | | | | |
| range of from | Storage modulus of | 2,003 | 2,211 | 1,227 | 526 |
| 0.001 Hz to | elasticity at 0.01 Hz | | | | |
| 1 Hz | (25° C.) | | | | |
| | Storage modulus of | 1,886 | 1,963 | 1,096 | 302 |
| | elasticity at 0.001 Hz | | | | |
| | (25° C.) | | | | |
| | Change ratio (%) of | −19 | −22 | −21 | −53 |
| | storage modulus of | | | | |
| | elasticity at 25° C. in | | | | |
| | range of from 0.001 Hz | | | | |
| | to 1 Hz | | | | |

The cleaning sheet and the transfer member provided with a cleaning function according to at least one embodiment of the present disclosure are each suitably used for cleaning of various kinds of substrate processing apparatus, such as production apparatus and inspection apparatus.

According to at least one embodiment of the present disclosure, the modified polybenzoxazole and the modified polybenzoxazole sheet each having small temperature dependence of its modulus of elasticity, each of which may be suitably used for forming a cleaning sheet that may be suitably used for a transfer member to be transferred in a substrate processing apparatus, can be provided. In addition, the cleaning sheet having small temperature dependence of its modulus of elasticity, including such modified polybenzoxazole sheet as a cleaning layer, can be provided. Further, the transfer member provided with a cleaning function, including such cleaning sheet and a transfer member, can be provided.

What is claimed is:

1. A modified polybenzoxazole, comprising a benzoxazole ring structure and two or more amide groups,
the modified polybenzoxazole having a storage modulus of elasticity at 1 Hz in a range of 0° C. to 100° C. of 200 MPa to 2,000 MPa.

2. The modified polybenzoxazole according to claim 1, wherein a change ratio of the storage modulus of elasticity at 1 Hz in a range of 0° C. to 100° C. is 50% or less.

3. The modified polybenzoxazole according to claim 1, wherein a change ratio of the storage modulus of elasticity at 25° C. in a range of 0.001 Hz to 1 Hz is 50% or less.

4. The modified polybenzoxazole according to claim 1, wherein the two or more amide groups are amide groups derived from a polyamine.

5. The modified polybenzoxazole according to claim 4, wherein the polyamine is at least one kind selected from the group consisting of a diamine compound having a polyether structure, an aliphatic diamine, and an aromatic diamine.

6. A modified polybenzoxazole sheet, comprising the modified polybenzoxazole of claim 1.

7. A cleaning sheet, comprising a cleaning layer, wherein the cleaning layer is the modified polybenzoxazole sheet of claim 6.

8. The cleaning sheet according to claim 7, further comprising a pressure-sensitive adhesive layer.

9. The cleaning sheet according to claim 7, further comprising a support.

10. A modified transfer member provided with a cleaning function, comprising:
the cleaning sheet of claim 7; and
a transfer member.
